(19) United States
(12) Patent Application Publication
(10) Pub. No.: US 2019/0032894 A1
(43) Pub. Date: Jan. 31, 2019

(54) FLEXIBLE LED LAMP MODULE

(71) Applicant: Shenzhen Fototech Photographic Equipment Co., Ltd, Shenzhen City, Guangdong (CN)

(72) Inventor: Chai Yee Ho, Shenzheng City, Guangdong (CN)

(73) Assignee: Shenzhen Fototech Photographic Equipment Co., Ltd, Shenzhen City, guangdong (CN)

(21) Appl. No.: 15/537,532

(22) PCT Filed: Jun. 2, 2016
(86) PCT No.: PCT/CN2016/084557

§ 371 Date: Jun. 19, 2017

(30) Foreign Application Priority Data
Apr. 22, 2016 (CN) 201620351611.5

(51) Int. Cl. F21V 17/00; F21V 19/00; F21V 15/01; H05K 1/18; F21V 23/06; F21V 17/10

(52) U.S. Cl. CPC F21V 17/002; F21V 19/0025; F21V 15/012; F21Y 2115/10; F21V 23/06; F21V 17/108; H05K 1/189

(57) ABSTRACT

There is disclosed a flexible LED lamp module, comprising: a flexible sheath (1) having an accommodating space; and a light-emitting component (2) capable of being disposed into the accommodating space. The light-emitting component (2) comprises a plurality of flexible LED lamp bands (21) and a lead (22) for electrically connecting the LED lamp bands (21). The sheath (1) and the light-emitting component (2) are configured in such a way that the accommodating space is filled with the plurality of flexible LED lamp bands (21) after the plurality of flexible LED lamp bands (21) are electrically connected by the lead (22). The flexible LED lamp module provided by the present application is simple and convenient to disassemble and assemble. If damaged, any internal group of flexible LED lamp bands can be easily pulled out for separate overhauling and replacement, and a use rate is improved. The LED lamp module can be transversely or longitudinally rolled to create various special light effects, and can be rolled up when not in use to save space.

### CROSS-REFERENCE TO RELATED APPLICATIONS

This application claims priority to International Patent Application No. PCT/CN2016/084557 filed on Jun. 2, 2016, and Chinese Patent Application No. 201620351611.5 filed on Apr. 22, 2016, the entire contents of which are incorporated herein by reference.

### TECHNICAL FIELD

In one aspect the present disclosure relates to the field of lamplight illumination, in particular to an LED lamp.

### BACKGROUND

There are two kinds of common LED lamp modules, and the light tubes of one kind of LED lamps are manufactured by a hard material to ensure fixed shapes per se. It is hard to change the shape of such LED lamps and when in use, such LED lamps cannot be easily spliced into characters or patterns in any shapes.

The other kind of LED lamps is lamp bands made of a flexible material. Multiple flexible LED lamp bands are connected by a lead and arranged into a preset shape and then are adhered onto a hard base plate to form an undetachable whole. Each LED lamp band can emit light in a specific color, and further an LED lamp module formed thereby can display preset characters or patterns. However, when certain LED lamp band is damaged, it has to be detached from the hard base plate. Since the LED lamp bands are fixed on the base plate in an adhesive manner, it is possible to pull peripheral LED lamp bands that can work normally in a replacement process, and cause an unnecessary loss. If no replacement is carried out, a display effect of the characters or patterns is affected. In addition, when the preset characters or patterns are changed, the entire LED lamp module needs to be remanufactured, while in fact, most of the original LED lamp bands are not damaged. As a result, tremendous resources are wasted.

Further, when not in use, these two kinds of LED lamps are hard to fold and store.

### SUMMARY

Therefore, the in one aspect, present disclosure provides a flexible LED lamp module to solve one or more of the above-mentioned existing technical problems.

According to one embodiment, a flexible LED lamp module is provided which comprises a flexible sheath; and a light-emitting component capable of being disposed into the flexible sheath. The light-emitting component comprises: a plurality of flexible LED lamp bands; and a lead for electrically connecting the LED lamp bands. Shapes of the plurality of flexible LED lamp bands are limited by the flexible sheath.

The flexible LED lamp module provided by a disclosed embodiment is simple and convenient to assemble and disassemble. If any of internal group of LED lamps is damaged, it can be easily pulled out to be separately overhauled and replaced, thereby improving a use rate. The LED lamp module can be transversely or longitudinally curved to create various special lighting effects and it can be rolled up when not in use to save space.

In some nonlimiting embodiments of this disclosure, the flexible sheath has an accommodating space which is filled with the plurality of the flexible LED lamp bands.

In some nonlimiting embodiments of the disclosure, the flexible sheath comprises a flexible bottom surface; a transparent flexible surface covering the flexible bottom surface. The accommodating space is formed between the flexible surface and the flexible bottom surface. One side of the accommodating space is provided with an opening. At least one flexible wall is disposed in the accommodating space and configured to connect the flexible surface and the flexible bottom surface. The flexible wall divides the accommodating space into at least two compartments along its length direction or width direction. Each of the compartments is communicated with the opening. And, each of the flexible LED lamp bands is capable of being disposed into the compartments in a row or column. The number of the LED lamp bands is smaller than or equal to that of the compartments.

The flexible wall is disposed in an example of the present embodiment and it divides the accommodating space into a plurality of compartments. Therefore, when the number of the LED lamp bands is smaller than that of the compartments, the LED lamp bands can be inserted into the compartments without affecting usage. Even by setting positions to insert into the compartments, more special visual effects can be created by the flexible LED lamp bands. In addition, such setting manner can provide convenience for separately replacing certain flexible LED lamp band. When the number of the flexible LED lamp bands is equal to that of the compartments, it can be ensured that each LED lamp band has a corresponding placing location, such that the LED lamp bands are capable of being disposed more orderly and steadily.

In some embodiments of the disclosure, at least two flexible walls are disposed and both ends of each flexible wall are fixedly connected to the flexible bottom surface. The flexible LED lamp bands are capable of being disposed into the compartments defined by the flexible walls and the flexible bottom surface.

In some embodiments of the disclosure, the flexible surface has a sewing line with the flexible bottom surface at a predetermined interval and there are at least three sewing lines. Therefore, a plurality of compartments is directly formed between the flexible surface and the flexible bottom surface to omit flexible walls.

In some embodiments of the disclosure, the flexible LED lamp bands in each compartment are connected in parallel by the lead and the tail end of the lead is provided with a power source plug.

In some embodiments of the disclosure, the flexible bottom surface is longer than the flexible surface at its side close to the opening or the flexible surface is longer than the flexible bottom surface at its side close to the opening, to form a covering end. A child tape of a velcro is disposed at the inner lateral surface of the covering end. And, a part of the outer lateral surface of the other one, close to the opening, is provided with a parent tape of the velcro.

Those skilled in the art should understand that the covering end provided with the velcro can seal the flexible LED lamp bands in the compartments such that the LED lamp bands cannot easily fall off. In addition, pollutants are also prevented from entering the compartments and making a contact with the flexible LED lamp band and thus the service life of the flexible LED lamp band is prevented from being shortened.

In some embodiments of the disclosure, the flexible bottom surface is made of a shading material.

In some embodiments of the disclosure, the flexible bottom surface is rectangular and the flexible sheath further comprises fixing bands disposed on top corners of the outer lateral surface of the flexible bottom surface. In this way, the flexible LED lamp module can be handheld or suspended on a support.

In some embodiments of the disclosure, the flexible LED lamp band comprises a flexible circuit board and LED light-emitting elements disposed on the flexible circuit board in parallel or in series.

### BRIEF DESCRIPTION OF THE DRAWINGS

FIG. 1 is a structural schematic diagram of a flexible LED lamp module of one embodiment;

FIG. 2 is a structural schematic diagram of one embodiment in which a light-emitting component of a flexible LED lamp module is totally inserted in a flexible sheath;

FIG. 3 is a top view of a flexible sheath of a flexible LED lamp module of one embodiment;

FIG. 4 is a side sectional view of a flexible LED lamp module of one embodiment;

FIG. 5 is a local enlarged view of a part A in FIG. 4;

FIG. 6 is another structural schematic diagram of the part A in FIG. 4;

FIG. 7 is a rear view of a flexible LED lamp module of one embodiment;

FIG. 8 is a schematic diagram of a flexible LED lamp module in a bending form of one embodiment; and

FIG. 9 is a schematic diagram of a flexible LED lamp module in another bending form of one embodiment.

### DETAILED DESCRIPTION

Although the accompanying drawings show exemplary embodiments of the disclosure, it should be appreciated that the present disclosure can be implemented in various ways and is not limited to the embodiments described here. On the contrary, these embodiments are merely provided for understanding the embodiments of the disclosure more thoroughly and are not limiting in any way to the scope of the invention as set forth in the claims.

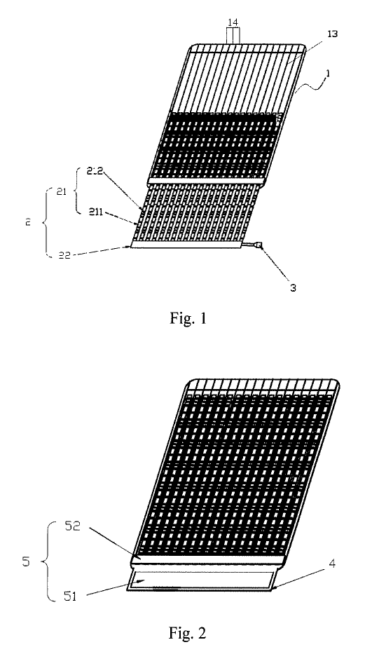

As shown in FIGS. 1-3, a flexible LED lamp module comprises a flexible sheath 1 having an accommodating space and a light-emitting component 2 capable of being disposed in the accommodating space.

The flexible sheath 1 comprises an opaque flexible bottom surface 11 and a transparent flexible surface 12. The flexible surface 12 is sewn on the flexible bottom surface 11 to form an accommodating space. An opening is disposed on one side of the accommodating space. A plurality of flexible walls 13 is formed in the above-mentioned accommodating space.

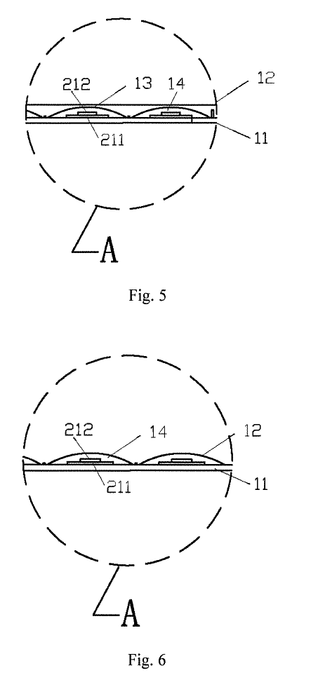

As shown in FIGS. 4 and 5, both ends of each of the flexible walls 13 are fixedly connected to the flexible bottom surface 11. Thus the flexible wall 13 and the flexible bottom surface 11 define a compartment 14. Each compartment 14 is communicated with the above-mentioned opening. The flexible wall 13 can be fixed in a sewing or adhesive manner. The flexible bottom surface 11 may also be transparent according to requirements from a use environment.

In one embodiment, one end of the flexible wall 13 is connected to the flexible bottom surface 11 and the other end thereof is connected to the flexible surface 12. The flexible wall 13 is distributed along the entire length direction of the accommodating space. A plurality of flexible walls 13 divide the accommodating space into a plurality of compartments 14 along the length direction of the accommodating space. Each compartment 14 is communicated with the above-mentioned opening. Namely, one side of each of the compartments 14 is open.

In one embodiment, as shown in FIG. 6, the flexible surface 12 and the flexible bottom surface 11 have a sewing line at every other distance interval. Therefore, the flexible surface 12 and the flexible bottom surface 11 can directly define a plurality of compartments 14 with one end of each of the compartments 14 being open.

The light-emitting component 2 comprises a plurality of flexible LED lamp bands 21 and a lead 22 for electrically connecting the LED lamp bands 21. Each LED lamp band 21 can be fully inserted into a corresponding compartment 14. Here, the number of the LED lamp bands 21 may be less than or equal to that of the compartments 14. The flexible LED lamp band 21 in each of the compartments 14 is connected in parallel through the lead 22 and the tail end of the lead 22 is provided with a power source plug 3.

In one embodiment, the flexible LED lamp band 21 comprises a flexible circuit board 211 and LED light-emitting elements 212 disposed on the flexible circuit board 211 in parallel or in series.

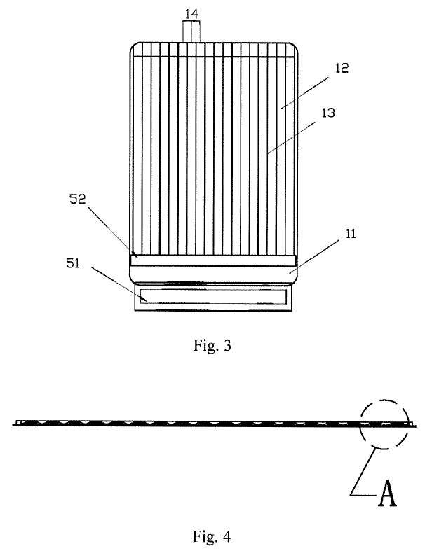

As shown in FIGS. 2 and 3, the flexible sheath 1 has an open side and the flexible bottom surface 11 is longer than the flexible surface 12 to form a covering end 4. The inner lateral surface of the covering end 4 is adhered to or sewed with a child tape 51 of a velcro 5 and the position of the outer lateral surface of the flexible surface 12, close to the opening, is adhered to or sewed with a parent tape 52 of the velcro 5. When the covering end 4 is folded upwards, the child tape 51 and the parent tape 52 can be exactly adhered together to enclose the plurality of flexible LED lamp bands 21 into the compartments 14. As shown above, because the lead 22 is flexible, even if the covering end 4 is folded to cover the open side, most of the lead 22 is wrapped in the covering end 4. Thus, there will be no influence to outward extension of the power source plug 3 on the tail end of the lead 22 from the flexible sheath 1 and a user may still connect the power source plug to a power source very conveniently.

Those skilled in the art should understand that the velcro 5 can be replaced with a button, a knot or a similar sealing lip on a food sealing bag.

As shown in FIG. 6, when the module needs to be disassembled, one can tear open the velcro 5, hold the flexible lead 22 by hand, and then easily pull out the whole light-emitting component 2 from the flexible cloth sheath 1. Certainly, one can also separately pull out the flexible LED lamp band strip 21 disposed in each of the compartments 14.

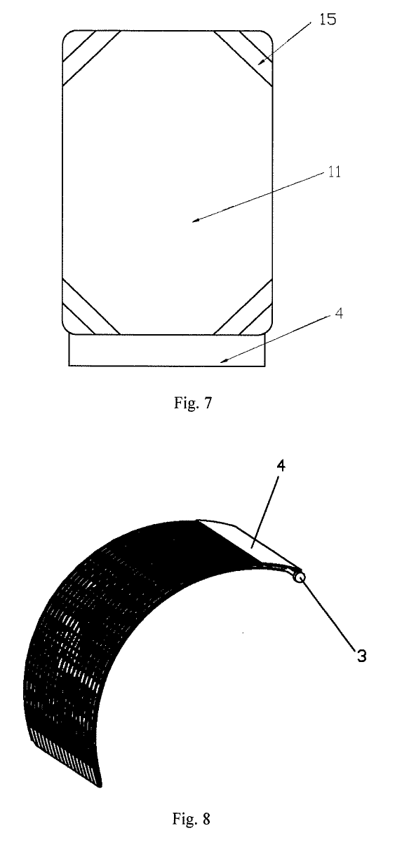

As shown in FIG. 7, fixing bands 15 can be further disposed on the outer lateral surface of the flexible bottom surface 11 of the flexible cloth sheath 1. The number of the fixing bands 15 can be determined according to an actual condition. The flexible cloth sheath 1 in the present embodiment is rectangular and the fixing bands 15 are disposed on all top corners of the flexible bottom surface 11. That is, the number of the fixing bands 15 is 4. When the flexible LED lamp module is required to be suspended somewhere for use as suspension points, the fixing bands 15 may be respectively sleeved on corresponding four top corners of a support frame. The fixing bands 15 may adopt elastic rubber bands or non-elastic cloth bands.

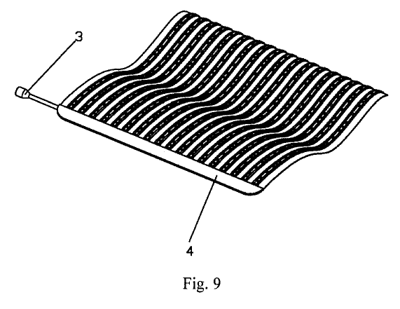

As shown in FIGS. 8 and 9, the LED lamp strip has good bendability by made of flexible materials. Therefore, this LED lamp band can be transversely or longitudinally rolled up, and various light effects can be thus created. In addition, when not in use, the LED lamp module can be rolled up for storage to save space.

The foregoing is only some embodiments of the present disclosure. For those ordinary skilled in the art, a plurality of modifications and improvements can be made without departing from the creative concept of the invention as set forth in the appended claims.

1. A flexible LED lamp module, characterized by comprising:
a flexible sheath; and
a light-emitting component capable of being disposed into the flexible sheath,
the light-emitting component includes:
a plurality of flexible LED lamp bands; and
a lead for electrically connecting the LED lamp bands,
wherein shapes of the plurality of flexible LED lamp bands being limited by the flexible sheath.

2. The flexible LED lamp module according to claim 1, characterized in that:
the flexible sheath has an accommodating space which is filled with the plurality of the LED lamp bands.

3. The flexible LED lamp module according to claim 1, characterized in that the flexible sheath comprises:
a flexible bottom surface;
a transparent flexible surface covering the flexible bottom surface, the accommodating space being formed between the flexible surface and the flexible bottom surface, and one side of the accommodating space is provided with an opening; and
at least one flexible wall disposed in the accommodating space and configured to connect the flexible surface and the flexible bottom surface, the flexible wall dividing the accommodating space into at least two compartments along a length direction or width direction thereof, each of the compartments being in communication with the opening, and
each of the flexible LED lamp bands is capable of being disposed into the compartments in a row or column, and the number of the LED lamp bands is smaller than or equal to that of the compartments.

4. The flexible LED lamp module according to claim 3, characterized in that:
at least two flexible walls are disposed and both ends of each flexible wall are fixedly connected to the flexible bottom surface, and the flexible LED lamp bands are capable of being disposed into the compartments defined by the flexible walls and the flexible bottom surface.

5. The flexible LED lamp module according to claim 3, characterized in that:
the flexible surface has a sewing line with the flexible bottom surface at a predetermined interval and at least three sewing lines are disposed.

6. The flexible LED lamp module according to claim 3, characterized in that:
the flexible LED lamp band in each of the compartments is connected in parallel by the lead; and
the tail end of the lead is provided with a power source plug.

7. The flexible LED lamp module according to claim 3, characterized in that:
the flexible bottom surface is longer than the flexible surface at its side close to the opening, or the flexible surface is longer than the flexible bottom surface at its side close to the opening, to form a covering end;
a child tape of a velcro is disposed at the inner lateral surface of the covering end; and
a part of the outer lateral surface of the other one, close to the opening, is provided with a parent tape of the velcro.

8. The flexible LED lamp module according to claim 3, characterized in that:
the flexible bottom surface is made of a shading material.

9. The flexible LED lamp module according to claim 4, characterized in that:
the flexible bottom surface is made of a shading material.

10. The flexible LED lamp module according to claim 5, characterized in that:
the flexible bottom surface is made of a shading material.

11. The flexible LED lamp module according to claim 6, characterized in that:
the flexible bottom surface is made of a shading material.

12. The flexible LED lamp module according to claim 7, characterized in that:
the flexible bottom surface is made of a shading material.

13. The flexible LED lamp module according to claim 1, characterized in that the flexible bottom surface is of a rectangular shape and the flexible sheath further comprises fixing bands disposed on top corners of the outer lateral surface of the flexible bottom surface.

14. The flexible LED lamp module according to claim 2, characterized in that the flexible bottom surface is of a rectangular shape and the flexible sheath further comprises fixing bands disposed on top corners of the outer lateral surface of the flexible bottom surface.

15. The flexible LED lamp module according to claim 3, characterized in that the flexible bottom surface is of a rectangular shape and the flexible sheath further comprises fixing bands disposed on top corners of the outer lateral surface of the flexible bottom surface.

16. The flexible LED lamp module according to claim 4, characterized in that the flexible bottom surface is of a rectangular shape and the flexible sheath further comprises fixing bands disposed on top corners of the outer lateral surface of the flexible bottom surface.

17. The flexible LED lamp module according to claim 5, characterized in that the flexible bottom surface is of a rectangular shape and the flexible sheath further comprises fixing bands disposed on top corners of the outer lateral surface of the flexible bottom surface.

18. The flexible LED lamp module according to claim 6, characterized in that the flexible LED lamp bands comprise:
a flexible circuit board; and
LED light-emitting elements disposed on the flexible circuit board in parallel or in series.

19. The flexible LED lamp module according to claim 1, characterized in that the flexible LED lamp bands comprise:
a flexible circuit board; and
LED light-emitting elements disposed on the flexible circuit board in parallel or in series.

20. The flexible LED lamp module according to claim 2, characterized in that the flexible LED lamp bands comprise:
a flexible circuit board; and
LED light-emitting elements disposed on the flexible circuit board in parallel or in series.
